(19) United States
(12) Patent Application Publication
(10) Pub. No.: US 2025/0132735 A1
(43) Pub. Date: Apr. 24, 2025

(54) CIRCUITS FOR AMPLFICATION OF A DELTA-SIGMA MODULATED BIT-STREAM

(71) Applicant: Djuro George Zrilic, Sante Fe, NM (US)

(72) Inventor: Djuro George Zrilic, Sante Fe, NM (US)

(21) Appl. No.: 18/445,567

(22) Filed: Oct. 23, 2023

(51) Int. Cl. H03F 3/04

(52) U.S. Cl. CPC H03F 3/04; H03F 2200/331

(57) ABSTRACT

The present invention relates to method and apparatus for the amplification by two of delta-sigma modulated bit-stream. The proposed amplifier consists of 5-bit up/down counter, and 2 delta-adders connected in the feedback of the counter. However, the proposed amplifier can be used for amplification of the attenuated sum of two or more synchronous Δ-Σ bit-streams.

### STATEMENT REGARDING FEDERALLY SPONSORED R&D

These research results are not sponsored by Government grants.

### U.S. PATENT DOCUMENTS

Dj. Zrilic, U.S. Pat. No. 10,594,335 B1, Mar. 17, 2020
Dj. Zrilic, U.S. Pat. No. 10,498,354 B1, Dec. 3, 2019
Dj. Zrilic, U.S. Pat. No. 10,110,246 B1, Oct. 23, 2018
Dj. Zrilic, U.S. Pat. No. 9,575,729 B1, Feb. 21, 2017
Dj. Zrilic, U.S. Pat. No. 9,525,430 B1, Dec. 20, 2016

### NAME OF PARTIES TO A JOINT RESEARCH AGREEMENT

Individual project of Dr. Djuro G. Zrilic

### BACKGROUND OF INVENTION

### 1. Field of the Invention

The present invention relates to a non-conventional processing of a delta-sigma (Δ-Σ) modulated bit-stream. The proposed digital circuit of amplifier is based on:
a use of a high-resolution Δ-Σ modulator as an analog-to-digital converter (ADC),
direct linear arithmetic operation on a Δ-Σ modulated bit stream, and
a use of standard digital logic circuits.

### 2. DESCRIPTION OF THE PRIOR ART

Even though there is an enormous amount of published literature on the subject of delta modulation [1], there are significantly smaller numbers of publications dealing with direct processing of delta-sigma modulated bit-stream. Traditionally, the decimation technique is used to bring the high bit-rate of a delta-sigma modulator to the speed of conventional DSP hardware. Direct processing of Δ-Σ M bit-stream (linear and nonlinear) provides many benefits including lower power and silicon area consumption (no bulky decimators), signal serialization, and simple and inexpensive circuits for mixed analog/digital signal processing applications.

Pioneering work in the area of arithmetic operation on a Δ-ΣM bit-stream started with publications of N. Kouvaras in 1978 [2]. He proposed the use of a conventional binary Full Adder, with interchanged roles of terminals for the Sum and Carry-Out. A block diagram of this circuit is shown in FIG. 3. Based on this invention, in a period 1978-2002, number of publications appeared by Greek authors and others. Significant work, in the area of linear and nonlinear processing of a 0-IM bit-stream was done by authors [3], [4]. In the period 1984-2021 Zrilic published a number of papers and patents related to direct processing Δ-ΣM bit-stream [5], [6].

The main disadvantage of proposed A-E adders is that they introduce an attenuation of one-half (½), when two Δ-Σ bit streams are added. N. Kouvaras was the first who defined the sum of two synchronous Δ-ΣM bit-streams as

$$Sn = 0.5 ( Xn + Y n ) + error$$

In FIG. 4 the simulation results are shown when two input signals of different frequencies are modulated with synchronous Δ-Σ modulators. Synchronous bit-streams, Xn and Yn, are added in delta adder (shown in FIG. 3), and after demodulation of sum (Sn bit-stream) the attenuated analog signal is obtained (one-half of input amplitude) [2]. In FIG. 4 the sum of two input signal (full line) and demodulated sum Sn is shown. We can see that added signals are attenuated by Y.

The objective of this patent application is to propose the novel circuit for amplification of Δ-ΣM bit-stream.

### BRIEF SUMMARY OF THE INVENTION

This invention introduces a novel digital circuit for amplification of a Δ-Σ modulated bit-stream. The operation of the proposed circuit will be apparent upon consideration of the following detailed description, taken in conjunction with the accompanying drawings. The present invention includes:
The circuit for amplification of a Δ-Σ bit-stream by two (2), based on use of up/down counter and delta adders (AA).
It is a primary objective of the present invention to solve the problem of attenuation of existing delta adders.
It is a further objective of the present invention to design amplifier with simple, less power consuming, and inexpensive digital logic circuits.
Finally, it is the objective of the present invention to design an amplification system on a chip (SoC), which includes amplification by two (2), and attenuators by one-half (½), one-quarter (¼), eight h (⅛), etc.

### BRIEF DESCRIPTION OF DRAWINGS

FIG. 1 (Prior Art) shows a block diagram of a first-order delta-sigma modulator. This block diagram is used to generate enclosed simulation results.

FIG. 2 (Prior Art) shows a block diagram of a second order delta-sigma modulator. This block diagram is used to generate enclosed simulation results.

FIG. 3 (Prior Art) shows delta-adder (ΔA). This delta adder is an ordinary binary adder with interchanged rolls of the sum (S) and carry-out (C) of a conventional binary adder [2]. This block diagram is used for generation waveforms shown in FIG. 4.

FIG. 4 shows an attenuated demodulated sum (dot line) of two sinusoidal waveforms at the output of Kouvaras delta-adder [2].

FIG. 5 shows a block diagram of novel amplifier (amplification by two) of a Δ-Σ bit-stream.

FIG. 6 shows an amplified sinusoidal waveform (dash line), when Δ-Σ bit-stream Xn is delivered directly to the first input of ΔA2 (switch in position 2).

FIG. 7 shows amplified demodulated bit-stream (On=Xn+Yn), dash line, when attenuated signal (dot line), S1=0.5(Xn+Yn), is delivered to the first input of ΔA2 (switch in position 1).

### DETAILED DEFINITION OF THE INVENTION

### Definition

By definition, the amplifier is an electric device which produces, at its output, signal Y=KX, where
X—is an input signal, and
K—is a gain (amplification)

Traditionally, amplification of a low-voltage electric signal is done in analog signal domain. With advancement of digital electronics and DSP, multiplication of two n-bit words is done using a “shift-and-add” technique. When a Δ-Σ modulator is used as an ADC, decimation of a Δ-Σ bit-stream is done first, and then all arithmetic operations are performed by ordinary DSP hardware. To avoid bulky and power consuming decimation hardware this invention proposes simple, inexpensive and low-power consuming digital logic Δ-Σ amplifier (K=2), and attenuators (K=½, ¼. ⅛, 1/16. . . ).

### How to Make the Invention

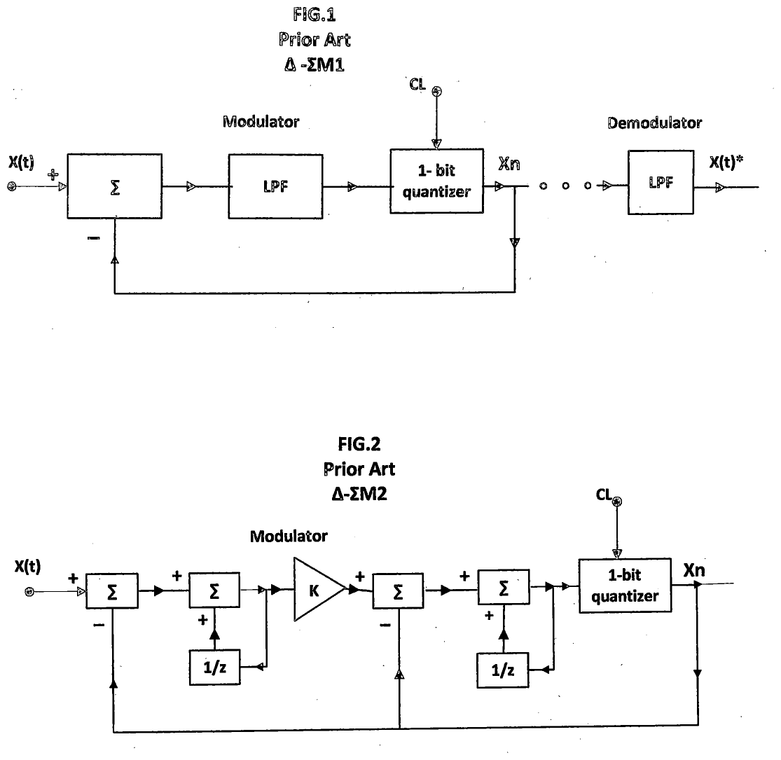

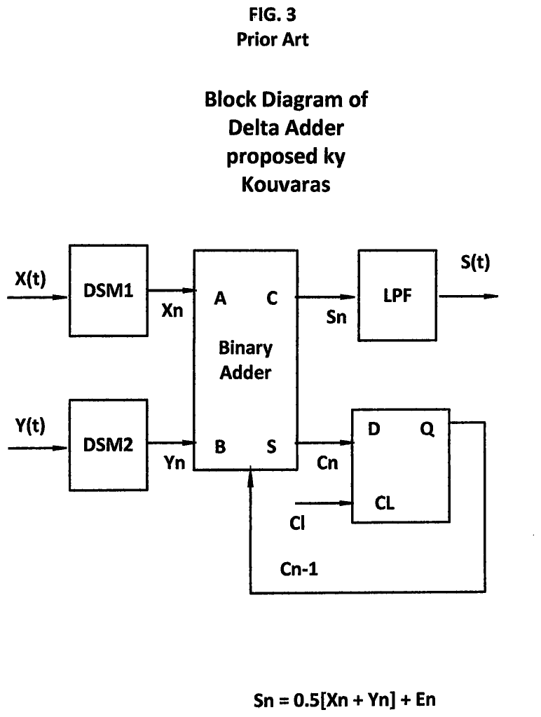

FIG. 1, FIG. 2, and FIG. 3 show the block diagrams of the Prior Art circuits used to generate simulation results.

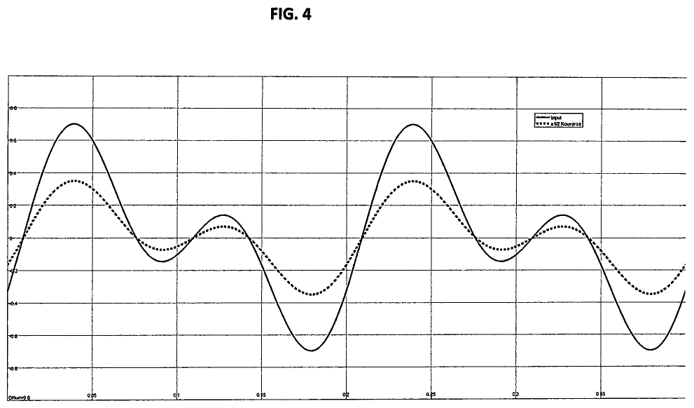

FIG. 4 shows simulation results of a Δ-Σ adder proposed by Kouvaras [2]. Dotted signal presents an attenuated amplitude of an input signal (full line) by one-half (½).

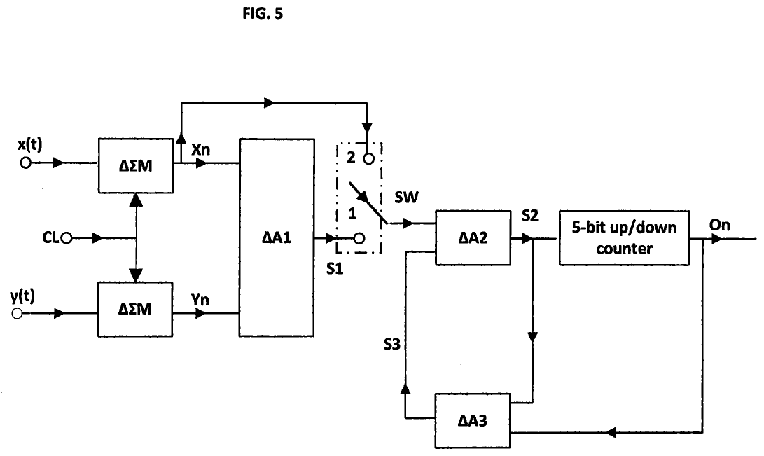

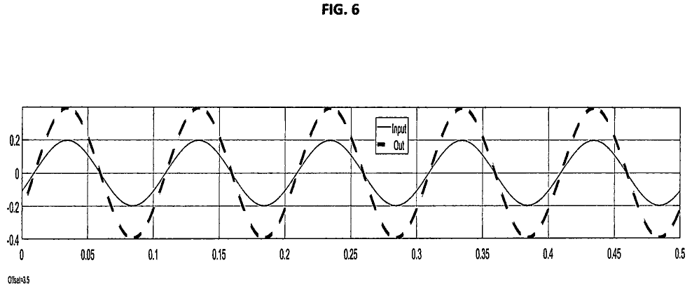

As can be amply seen FIG. 5 represents a novel amplifier circuit.

To overcome attenuation of a Δ-Σ adder, the novel system of amplification by 2 is proposed in FIG. 5. It consists of: two synchronous Δ-Σ modulators, delta adders ΔA1, ΔA2, AA3, and 5-bit up/down counter.

FIG. 6 shows the case when a Δ-Σ bit-stream Xn is delivered to the first input of ΔA2 (SW in position 2). A dashed line presents amplified sinusoidal input by 2.

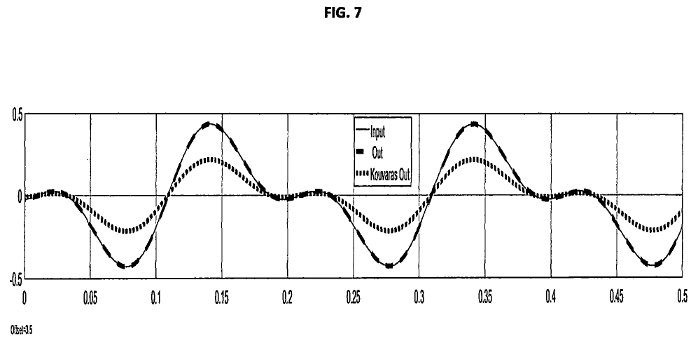

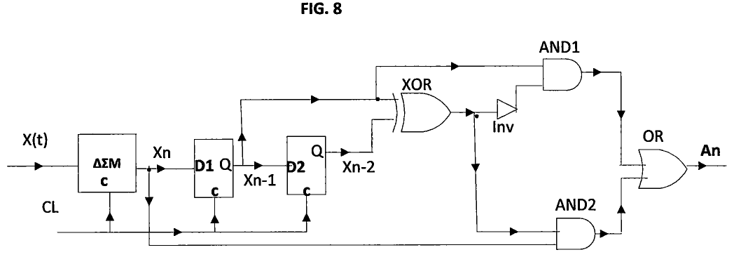

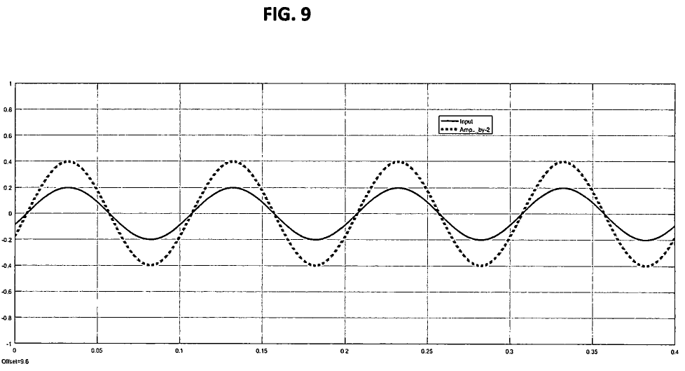

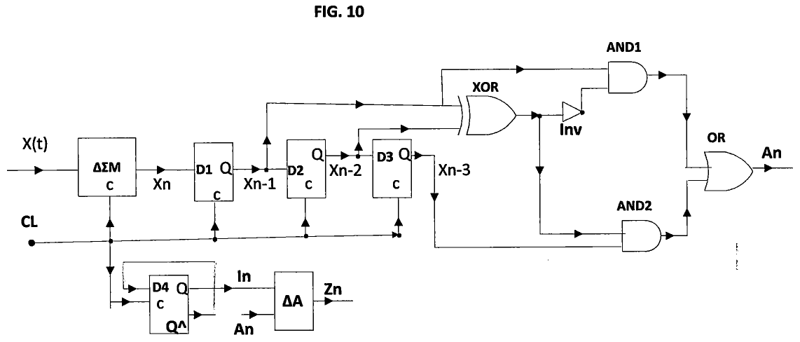

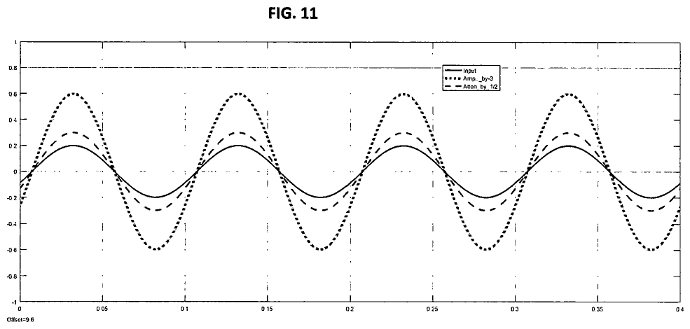

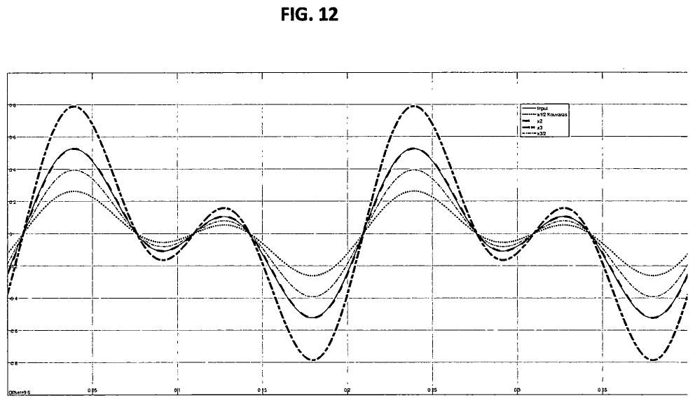

FIG. 7 shows the results of simulation when two input signals, are modulated by two synchronous Δ-Σ modulators, and their bit-streams, Xn and Yn, are added in ΔA1. The full line represents the sum of signals (x(t)+y(t)) of two different frequencies, and the dotted line represents demodulated sum of these two signals (attenuated/demodulated bit stream S1). The dashed line in FIG. 7 represents the demodulated sum of bit-stream On. One can see that attenuated sum S1 (dotted line) is amplified by two (dashed line).

### How to Use the Invention

Δ-Σ modulation is well established as the one-bit, high resolution (24 bit), low power consuming analog-to-digital converter (ADC). Oversampled Δ-Σ ADC has many uses in low-frequency areas of bio-medical applications, instrumentation, control systems, sensor edge devices, environmental sensing systems, acoustics′, etc. For example, environmental sensing networks, with many sensors, deliver massive data sets. These massive data represent a substantial burden on the communication links between the sensors (edge devices) and server. Δ-Σ modulator may incorporate several multiplexed analog sensing signals at its input. Cascading Δ-Σ amplifiers, multiple amplification can be achieved (by 2,4 . . . ). Or, cascading Δ-Σ adders' multiple attenuation can be achieved (by ½, ¼. . . ).

### OTHER PUBLICATIONS

[1.]J. Candy, G. Temes, Editors, Oversampling Delta-Sigma Data Converters, IEEE Press, 1992, ISBN: 0-87942-285-8,
[2.]N. Kouvaras, “Operations on Delta-Modulated Signals and Their Applications in the Realization of Digital Filters”, The Radio and Electrical Engineering, September 1078, No. 9, pp. 432-438.
[3.]Y. Hidaka, H. Fujisaka, M. Sakimoto, and M. Morisue, “Arithmetic and Piecewise Linear Operations on Sigma-Delta Modulated Signals”, in 2002 9^{th} International Conference on Electronics, Circuits and System, Vol. 3, pp. 983-986.
[4.] H. Fujisaka, T. Kamino, C. J. Ahn, and K. Haeiwa, “Sorter-Based Arithmetic Circuit for Sigma-Delta Domain Signal Processing I: Addition, Approximate Transcendental Functions and Log-domain Operations”, Circuits and Systems I Modulation”: Regular Papers, IEEE Transaction, Vol. 59, No. 9, pp. 1952-1965, September 2012.
[5.] Dj. G. Zrilic, “Circuits and System Based on Delta, Linear, Nonlinear and Mixed Mode Processing”, Springer 2005, ISBN 3-540-23751-8.
[6.] Dj. G. Zrilic “Functional Processing of Delta-Sigma Bit-Stream”, Springer 2020, ISBN 978-3-030-47647-2.

What is claimed is:

1. A Δ-Σ amplifier for amplification by two (2), comprising:
a Δ-Σ modulator for producing pulse density bit-stream Xn;
a 5-bit up/down counter;
two feedback delta adders, ΔA2 and ΔA3.

2. A Δ-Σ amplifier for amplification by two (2), comprising:
a Δ-Σ modulator for producing pulse density bit-stream Xn;
two D flip-lops;
five digital logic gates.

3. A Δ-Σ amplifier for amplification by three (3) comprising:
a Δ-Σ modulator for producing pulse density bit-stream Xn;
three D flip-flops;
five digital logic gates;
a generator of idle sequence In;
a delta adder (ΔA) to produce attenuated signal Zn.
